(19) United States
(12) Patent Application Publication
(10) Pub. No.: US 2025/0132295 A1
(43) Pub. Date: Apr. 24, 2025

(54) EPITAXIALLY-GROWN SUBSTRATE AND SEMICONDUCTOR DEVICE MANUFACTURING METHOD

(71) Applicant: Murata Manufacturing Co., Ltd., Kyoto-fu (JP)

(72) Inventor: Masayuki AOIKE, Nagaokakyo-shi (JP)

(73) Assignee: Murata Manufacturing Co., Ltd., Kyoto-fu (JP)

(21) Appl. No.: 18/917,659

(22) Filed: Oct. 16, 2024

(30) Foreign Application Priority Data
Oct. 20, 2023 (JP) 2023-180979

(51) Int. Cl. H01L 25/07; H01L 29/04; H01L 29/205; H01L 29/36

(52) U.S. Cl. CPC H01L 25/072; H10D 62/40; H10D 62/60; H10D 62/824

(57) ABSTRACT

An epitaxially-grown substrate includes: a substrate made of a III-V-group compound semiconductor containing Ga or In as a III-group element; a sacrificial layer epitaxially grown on the substrate; and a semiconductor layer epitaxially grown on the sacrificial layer. The sacrificial layer includes a layer made of a mixed-crystal semiconductor containing Al or In as a III-group element, a composition ratio of Al or In varies in a thickness direction, and a location indicating a local maximum value of the composition ratio of Al or In is positioned inside other than a lower surface and an upper surface of the sacrificial layer.

### CROSS-REFERENCE TO RELATED APPLICATION

This application claims benefit of priority to Japanese Patent Application No. 2023-180979, filed Oct. 20, 2023, the entire content of which is incorporated herein by reference.

### BACKGROUND

### Technical Field

The present disclosure relates to epitaxially-grown substrates and semiconductor device manufacturing methods.

### Background Art

A technique has been known in which a sacrificial layer made of AlGaAs, AlAs, or the like is epitaxially grown on a substrate made of GaAs or the like, a semiconductor layer is epitaxially grown on the sacrificial layer, and then the sacrificial layer is etched to cause the semiconductor layer to be isolated from the substrate as described, for example, in Japanese Patent Nos. 2658493 and 5394091. For etching the sacrificial layer, a groove is formed from the semiconductor layer to reach the lower surface of the sacrificial layer. After the groove is formed, the sacrificial layer is etched from a side surface of the groove.

### SUMMARY

Etching the sacrificial layer proceeds from an end face exposed to the groove to a lateral direction. Due to crystal face orientation dependency of the etching rate, there may be a case in which a portion of the sacrificial layer in contact with the semiconductor layer is etched faster than a portion in contact with the substrate. If etching proceeds with this condition, the sacrificial layer and the semiconductor layer are connected at a subtle region, and the sacrificial layer and the substrate become in a state of being connected with a relatively wide region. If the substrate and the sacrificial layer fall from the semiconductor layer with the sacrificial layer and the semiconductor layer being connected at the subtle region, a crack or the like occurs in the semiconductor layer.

Therefore, the present disclosure provides an epitaxially-grown substrate in which an occurrence of a crack in a semiconductor layer can be suppressed when the substrate is isolated from the semiconductor layer. The present disclosure also provides a semiconductor device manufacturing method using this epitaxially-grown substrate.

According to an aspect of the present disclosure, there is provided an epitaxially-grown substrate including a substrate made of a III-V-group compound semiconductor containing Ga or In as a III-group element; a sacrificial layer epitaxially grown on the substrate; and a semiconductor layer epitaxially grown on the sacrificial layer. The sacrificial layer includes a layer made of a mixed-crystal semiconductor containing Al or In as a III-group element, a composition ratio of Al or In varies in a thickness direction, and a location indicating a local maximum value of the composition ratio of Al or In is positioned inside other than a lower surface and an upper surface of the sacrificial layer.

According to another aspect of the present disclosure, there is provided a semiconductor device manufacturing method including forming at least one semiconductor element of a transistor and a diode on the semiconductor layer of the above-described epitaxially-grown substrate; and performing etching removal of the sacrificial layer to separate the substrate from the semiconductor layer.

At a location of the sacrificial layer indicating a local maximum value of a composition ratio of Al or In, the etching rate with respect to an acidic etchant or an alkaline etchant is relatively large. For this reason, when the sacrificial layer is etched, etching proceeds relatively early at locations other than the lower surface and the upper surface of the sacrificial layer, and a portion on a substrate side and a portion on a semiconductor layer side are isolated at the locations other than the lower surface and the upper surface of the sacrificial layer. Since the sacrificial layer on the substrate side and the sacrificial layer on the semiconductor layer side are isolated at a location away from a surface of the semiconductor layer, a crack less tends to occur in the semiconductor layer at the time of isolation.

### BRIEF DESCRIPTION OF THE DRAWINGS

FIG. 1A is a sectional view of an epitaxially-grown substrate according to a first embodiment;

FIG. 1B is a graph depicting one example of a distribution of etching rates of layers of the epitaxially-grown substrate;

FIGS. 2A, 2B, and 2C are sectional views of the epitaxially-grown substrate, a preliminary substrate, and an adhesive layer in the course of a procedure of isolating a semiconductor layer of the epitaxially-grown substrate according to the first embodiment from a substrate;

FIGS. 3A and 3C are sectional views of the epitaxially-grown substrate, the preliminary substrate, and the adhesive layer in the course of the procedure of isolating the semiconductor layer of the epitaxially-grown substrate according to the first embodiment from the substrate;

FIG. 3B is a view depicting a positional relation in plan view among the substrate, the semiconductor layer, and a sacrificial layer in the course of the procedure depicted in FIG. 3A;

FIG. 3D is a sectional view of the semiconductor layer, the preliminary substrate, and the adhesive layer, with the substrate isolated;

FIGS. 4A and 4B are views depicting a procedure of isolating a substrate from a semiconductor layer in an epitaxially-grown substrate according to a comparative example;

FIG. 5A is a graph depicting a distribution of Al composition ratios in a thickness direction in the sacrificial layer of the epitaxially-grown substrate according to the first embodiment;

FIGS. 5B to 5F are graphs depicting distributions of Al composition ratios in the thickness direction in sacrificial layers of epitaxially-grown substrates according to modifications of the first embodiment;

FIGS. 6A to 6F are graphs depicting distributions of In composition ratios in a thickness direction in sacrificial layers of epitaxially-grown substrates according to other modifications of the first embodiment;

FIG. 7 is a sectional view of an epitaxially-grown substrate according to a second embodiment;

FIGS. 8A and 8B are sectional views of a semiconductor device according to a third embodiment in the course of manufacture; and

FIGS. 9A and 9B are sectional views of the semiconductor device according to the third embodiment in the course of manufacture.

### DETAILED DESCRIPTION

### First Embodiment

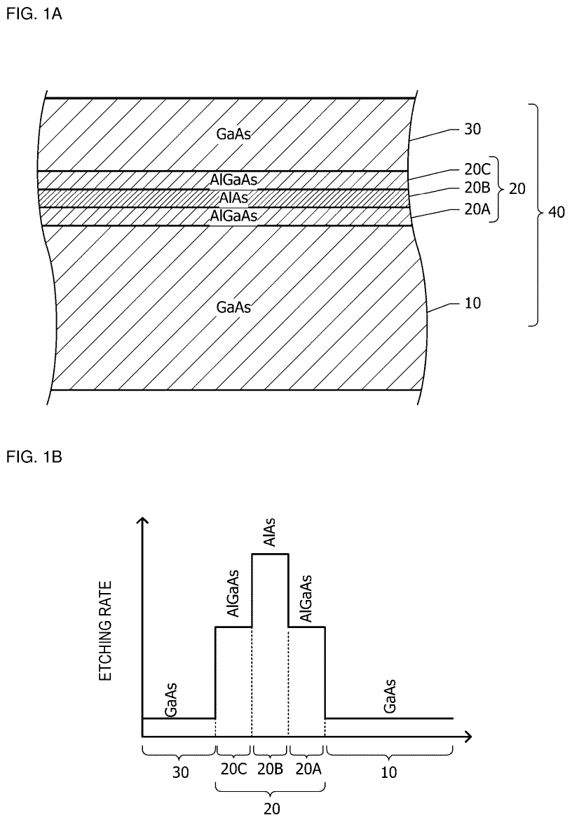

With reference to FIGS. 1A to 4B, an epitaxially-grown substrate according to a first embodiment is described.

FIG. 1A is a sectional view of an epitaxially-grown substrate 40 according to the first embodiment. On a substrate 10 made of a III-V-group compound semiconductor containing Ga as a III-group element, for example, GaAs, a sacrificial layer 20 and a semiconductor layer 30 are epitaxially grown in this order. The sacrificial layer 20 includes layers 20A and 20C made of a III-V-group mixed-crystal semiconductor containing Al as a III-group element, for example, AlGaAs. The sacrificial layer 20 further includes, between these layers, a layer 20B made of a compound semiconductor containing Al as a III-group element, for example, AlAs. The semiconductor layer 30 includes a layer made of a compound semiconductor having lattice matching with the substrate 10, for example, GaAs.

In the epitaxially-grown substrate 40 according to the first embodiment, the semiconductor layer 30 is isolated from the substrate 10 by etching removal of the sacrificial layer 20 and is used as the thin semiconductor layer 30. For example, before isolated from the substrate 10, the semiconductor layer 30 has various electronic circuit elements such as a transistor, a diode, and other passive elements formed thereon, and is then isolated from the substrate 10. With this, it is possible to fabricate very-thin integrated circuit elements.

FIG. 1B is a graph depicting one example of a distribution of etching rates of layers of the epitaxially-grown substrate 40. The horizontal axis represents the position of the epitaxially-grown substrate 40 in a thickness direction, and the vertical axis represents an etching rate. As the Al composition ratio increases, the etching rate when wet etching is performed with an acidic etchant or an alkaline etchant increases. Thus, the etching rate of the layer 20B made of AlAs is higher than the etching rate of the layers 20A and 20C made of AlGaAs. The etching rate of the substrate 10 and the semiconductor layer 30 made of GaAs is sufficiently low, compared with the etching rates of the three layers 20A, 20B, and 20C included in the sacrificial layer 20.

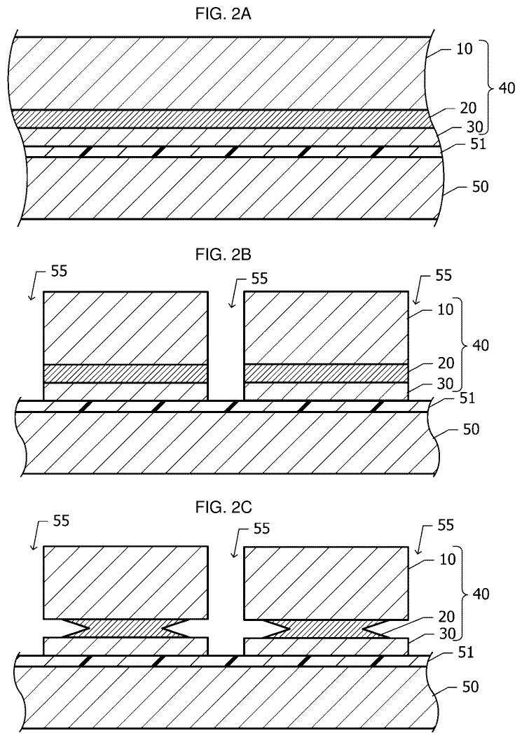

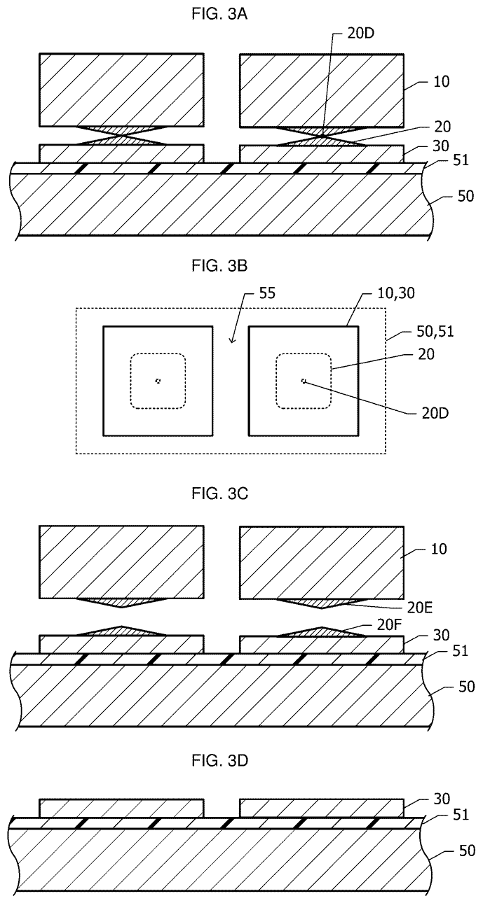

Next, with reference to FIGS. 2A to 3D, a procedure of isolating the semiconductor layer 30 of the epitaxially-grown substrate 40 according to the first embodiment from the substrate 10 is described. FIGS. 2A, 2B, 2C, 3A, and 3C are sectional views of the epitaxially-grown substrate 40, a preliminary substrate 50, and an adhesive layer 51 in the course of the procedure of isolating the semiconductor layer 30 of the epitaxially-grown substrate 40 according to the first embodiment from the substrate 10. FIG. 3B is a view depicting a positional relation in plan view among the substrate 10, the semiconductor layer 30, and the sacrificial layer 20 in the course of the procedure depicted in FIG. 3A. FIG. 3D is a sectional view of the semiconductor layer 30, the preliminary substrate 50, and the adhesive layer 51, with the substrate 10 isolated.

As depicted in FIG. 2A, the semiconductor layer 30 of the epitaxially-grown substrate 40 according to the first embodiment is opposed to the preliminary substrate 50, and the epitaxially-grown substrate 40 is bonded to the preliminary substrate 50 with the adhesive layer 51. As the preliminary substrate 50, for example, a silicon substrate is used, and a polyimide-based adhesive is used as the adhesive layer 51.

As depicted in FIG. 2B, the epitaxially-grown substrate 40 is cut with a dicing machine to form isolation grooves 55, thereby dividing the epitaxially-grown substrate 40 into a plurality of small pieces (chips). The plurality of small pieces of the epitaxially-grown substrate 40 are bonded to the preliminary substrate 50 and supported thereby.

As depicted in FIG. 2C, the epitaxially-grown substrate 40 after divided into small pieces are immersed in an acidic etchant or an alkaline etchant for wet etching of the sacrificial layer 20. The sacrificial layer 20 is etched from an exposed end face toward a lateral direction. The etching rate of the sacrificial layer 20 is, as depicted in FIG. 1B, high at a center portion in the thickness direction and low near interfaces with the substrate 10 and the semiconductor layer 30. Therefore, the etching depth of the center portion of the sacrificial layer 20 in the thickness direction to the lateral direction is relatively deep, compared with the other portions.

When etching further proceeds, as depicted in FIGS. 3A and 3B, at the center portion of the sacrificial layer 20 in the thickness direction, a state is obtained in which a portion of the sacrificial layer 20 on a substrate 10 side and a portion of the sacrificial layer 20 on a semiconductor layer 30 side are connected at a point-like subtle region 20D. When etching still further proceeds, as depicted in FIG. 3C, the sacrificial layer 20 is isolated into a portion 20E on a substrate 10 side and a portion 20F on a semiconductor layer 30 side.

After the sacrificial layer 20 is isolated into two portions 20E and 20F, etching further proceeds and, as depicted in FIG. 3D, the portion 20F (FIG. 3C) remaining on a semiconductor layer 30 side is completely removed. With the process so far, the substrate 10 (FIG. 3C) can be isolated from the semiconductor layer 30. The semiconductor layer 30 is almost not etched with the etchant.

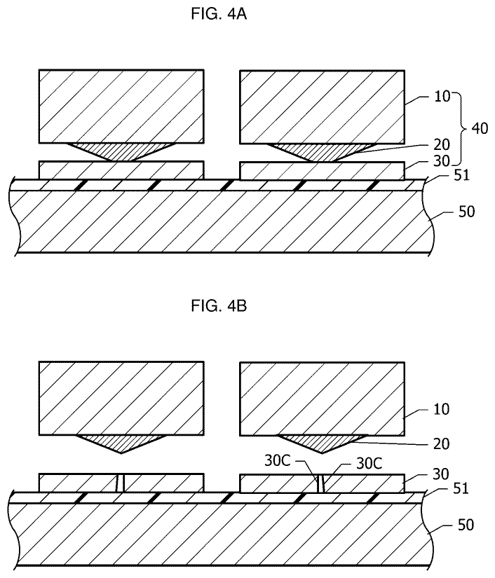

Next, excellent effects of the first embodiment are described in comparison with a comparative example depicted in FIGS. 4A and 4B.

FIGS. 4A and 4B are views depicting a procedure of isolating the substrate 10 from the semiconductor layer 30 in the epitaxially-grown substrate 40 according to the comparative example. In the epitaxially-grown substrate 40 according to the comparative example, the Al composition ratio of the sacrificial layer 20 is constant with respect to the thickness direction. When the sacrificial layer 20 is etched from the exposed end face, due to crystal face orientation dependency of the etching rate, as depicted in FIG. 4A, the sacrificial layer 20 becomes in a truncated pyramid shape having a crystal face with a low etching rate as an inclined surface. A surface (upper surface) of the truncated pyramid shape connected to the semiconductor layer 30 is smaller than a surface (lower surface) of the truncated pyramid shape connected to the substrate 10.

When etching further proceeds, as depicted in FIG. 4B, the upper surface of the sacrificial layer 20 in the truncated pyramid shape becomes almost a point-like shape, and the sacrificial layer 20 is isolated from the semiconductor layer 30. Immediately before the sacrificial layer 20 is isolated from the semiconductor layer 30, the sacrificial layer 20 is supported by a subtle point-like region with respect to the semiconductor layer 30. With stress concentrating on this subtle point-like region, cracks 30C tend to occur in the semiconductor layer 30.

By contrast, in the first embodiment, the etching rate varies with respect to the thickness direction of the sacrificial layer 20, and a portion having a maximum etching rate is positioned inside the sacrificial layer 20. Thus, as depicted in FIGS. 3A and 3B, immediately before the substrate 10 is isolated from the semiconductor layer 30, a state is such that a portion of the sacrificial layer 20 on a substrate 10 side and a portion of the sacrificial layer 20 on a semiconductor layer 30 side are connected at the subtle point-like region. That is, a state in which a connecting location between the sacrificial layer 20 and the semiconductor layer 30 (FIGS. 3A and 3C) becomes in a subtle point-like shape does not occur. Thus, an excellent effect can be obtained in which a crack less tends to occur in the semiconductor layer 30. To perform etching removal of the sacrificial layer 20 with priority with respect to the substrate 10 and the semiconductor layer 30, it is preferable to set a maximum value of the Al composition ratio in the sacrificial layer 20 at a value larger than or equal to 0.5.

When the layer 20A (FIG. 1A) made of AlGaAs is omitted and the layer 20B made of AlAs is epitaxially grown on the substrate 10 directly, the crystal quality of the sacrificial layer 20 is degraded due to lattice mismatching. As a result, the crystal quality of the semiconductor layer 30 epitaxially grown on the sacrificial layer 20 is also degraded. The layer 20A made of AlGaAs arranged between the layer 20B made of AlAs and the substrate 10 made of GaAs has a function of mitigating lattice mismatching. This allows suppression of degradation of crystallinity of the sacrificial layer 20 and the semiconductor layer 30.

Next, a preferable range of thicknesses of the sacrificial layer 20 is described.

Due to lattice mismatching between the substrate 10 and the sacrificial layer 20, distortion occurs in the sacrificial layer 20. However, if the sacrificial layer 20 is made too thick, dislocation occurs in the sacrificial layer 20 to mitigate distortion. The sacrificial layer 20 preferably has a thickness to the extent that distortion mitigation does not occur. Also, if the sacrificial layer 20 is made too thin, in an etching process depicted in FIG. 2C, the etchant becomes less prone to enter a space where the sacrificial layer 20 is removed. The sacrificial layer 20 preferably has a thickness to the extent that the entry of the etchant is not prevented.

Next, a preferable relation of thicknesses of the substrate 10, the sacrificial layer 20, and the semiconductor layer 30 is described.

The substrate 10 functions as a support substrate for mechanically supporting the semiconductor layer 30 in a semiconductor process of forming various electronic circuit elements, for example, a transistor, a diode, a capacitor, an inductor, and so forth, on the thin semiconductor layer 30. The semiconductor layer 30 has a thickness to the extent that its shape cannot be stably maintained by itself. Also, isolating the substrate 10 from the semiconductor layer 30 is to make a thin film of a member including the semiconductor layer 30 having the electronic circuit elements formed thereon. Therefore, the thickness of the semiconductor layer 30 is preferably thinner than the thickness of the substrate 10.

When a transistor or the like is formed on the semiconductor layer 30, it is preferable to use, as the substrate 10, a material having lattice matching with a compound semiconductor of a single layer configuring the transistor. In other words, the semiconductor layer 30 preferably includes a layer made of a compound semiconductor having lattice matching with the substrate 10.

If the sacrificial layer 20 is too thick, dislocation tends to occur in the sacrificial layer 20, degrading the crystal quality of the semiconductor layer 30 to be epitaxially grown on the sacrificial layer 20. To suppress degradation in crystal quality of the semiconductor layer 30, it is preferable to make the sacrificial layer 20 as thin as possible. By way of example, the thickness of the sacrificial layer 20 is preferably thinner than the thickness of the semiconductor layer 30. For example, the thickness of the sacrificial layer 20 is 0.01 μm or more and 0.5 μm or less, and the thickness of the semiconductor layer 30 is 0.5 μm or more and 10 μm or less.

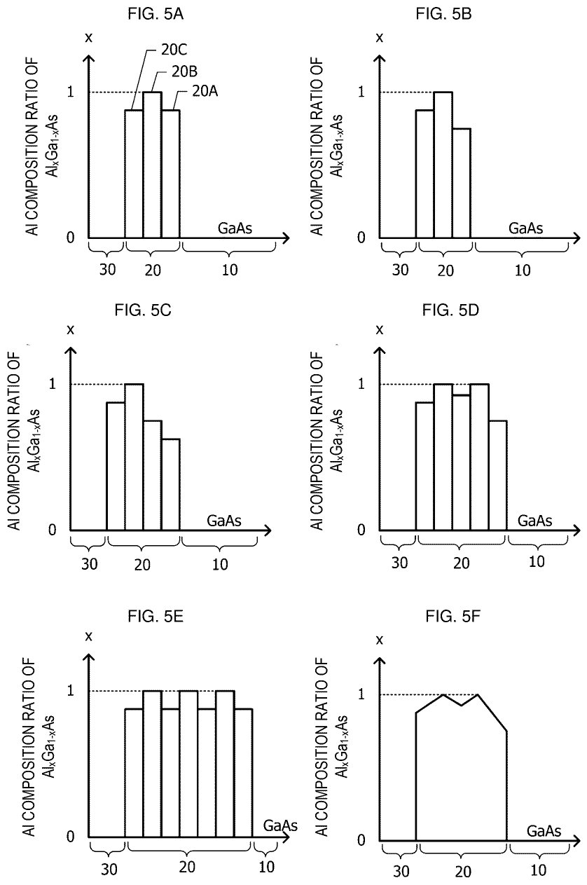

Next, with reference to FIGS. 5A to 5F, the epitaxially-grown substrate according to the first embodiment and epitaxially-grown substrates according to the modifications of the first embodiment are described. FIG. 5A is a graph depicting a distribution of Al composition ratios in the thickness direction in the sacrificial layer 20 of the epitaxially-grown substrate 40 according to the first embodiment. FIGS. 5B to 5F are graphs depicting distributions of Al composition ratios in the thickness direction in the sacrificial layers 20 of the epitaxially-grown substrates 40 according to modifications of the first embodiment. In every example, the sacrificial layer 20 is formed of AlₓGa₁₋ₓAs. The horizontal axis of the graph depicted in each of FIGS. 5A to 5F represents positions of the substrate 10, the sacrificial layer 20, and the semiconductor layer 30 in the thickness direction, and the vertical axis represents Al composition ratio x.

As depicted in FIG. 5A, in the first embodiment, the sacrificial layer 20 is formed of three layers, and the center layer 20B has an Al composition ratio x of 1 and the layers 20A and 20C on both sides have the same Al composition ratio x, which is smaller than 1.

Also in the modification depicted in FIG. 5B, the center layer of the sacrificial layer 20 has an Al composition ratio x of 1. However, the Al composition ratio x of a layer on a substrate 10 side is smaller than the Al composition ratio x of a layer on a semiconductor layer 30 side. With this structure, lattice mismatching at an interface between the substrate 10 and the sacrificial layer 20 is small, thereby enhancing the effect of suppressing degradation of the crystal quality of the sacrificial layer 20 and the semiconductor layer 30.

Also, since the Al composition ratio x of a layer of the sacrificial layer 20 in contact with the semiconductor layer 30 is larger than the Al composition ratio x of a layer in contact with the substrate 10, the etching rate of the layer of the sacrificial layer 20 in contact with the semiconductor layer 30 is higher than the etching rate of the layer in contact with the substrate 10. Thus, the portion 20F of the sacrificial layer 20 on the semiconductor layer 30 side depicted in FIG. 3C is smaller than the portion 20E on the substrate 10 side. As a result, after the substrate 10 is isolated from the semiconductor layer 30, the portion 20F of the sacrificial layer 20 remaining on the semiconductor layer 30 side can be removed in a shorter time.

In the modification depicted in FIG. 5C, between a layer with an Al composition ratio x of 1 and the substrate 10, two layers with different Al composition ratios x both smaller than 1 are arranged. Of these two layers, the Al composition ratio x of the layer on a substrate 10 side is relatively lower. By increasing the Al composition ratios stepwise from the substrate 10 toward the layer with an Al composition ratio x of 1, it is possible to bring the lattice constant of a portion of the sacrificial layer 20 in contact with the substrate 10 closer to the lattice constant of the substrate 10, while suppressing a steep change in the lattice constant. With this, degradation in crystal quality due to lattice mismatching can be further suppressed.

In the modification depicted in FIG. 5D, regarding the thickness direction of the sacrificial layer 20, the Al composition ratio x is 1 at two locations. In the modification depicted in FIG. 5E, regarding the thickness direction of the sacrificial layer 20, the Al composition ratio x is 1 at three locations. In a layer having an Al composition ratio x of 1 with the largest lattice mismatching with respect to the substrate 10, relatively large distortion resides due to lattice mismatching. When the thickness of each layer having the Al composition ratio x of 1 is thick, dislocation occurs to mitigate distortion.

With a structure in which the Al composition ratio x is 1 at a plurality of locations regarding the thickness direction of the sacrificial layer 20, it is possible to thicken the sacrificial layer 20 without mitigating distortion in the sacrificial layer 20 (without causing dislocation to occur). When the sacrificial layer 20 is thicken, in an etching process depicted in FIG. 2C, the etchant is prone to enter between the substrate 10 and the semiconductor layer 30, and it is thereby possible to enhance stability of the etching process of the sacrificial layer 20.

The locations where the Al composition ratio x is 1 can be arranged at a plurality of locations larger than or equal to four locations, other than two or three locations, regarding the thickness direction of the sacrificial layer 20.

In the modification depicted in FIG. 5D, as with the modification depicted in FIG. 5B, the Al composition ratio x of the layer in contact with the substrate 10 is lower than the Al composition ratio x of a layer in contact with the semiconductor layer 30. Thus, as with the modification depicted in FIG. 5B, lattice mismatching at an interface between the substrate 10 and the sacrificial layer 20 can be mitigated. Note that also in the modification depicted in FIG. 5E, the Al composition ratio x of the layer in contact with the substrate 10 may be lower than the Al composition ratio x of the layer in contact with the semiconductor layer 30.

In the modification depicted in FIG. 5F, the Al composition ratio x continuously varies in the sacrificial layer 20 to the thickness direction. Also in this case, as with the modification depicted in FIG. 5D, the Al composition ratio x is 1 at two locations in the thickness direction of the sacrificial layer 20. If the Al composition ratio x discontinuously varies, stress tends to concentrate on an interface of the layer where the Al composition ratio x is discontinuous. By continuously varying the Al composition ratio x, it is possible to suppress stress localization. As a result, the crystal quality of the sacrificial layer 20 can be enhanced.

Furthermore, as with the modification depicted in FIG. 5D, the Al composition ratio x of the sacrificial layer 20 at the interface with the substrate 10 is lower than the Al composition ratio x of the sacrificial layer 20 at the interface with the semiconductor layer 30. With this, lattice mismatching can be suppressed, and the crystal quality of the semiconductor layer 30 can be enhanced.

In the first embodiment depicted in FIG. 5A and the modifications of the first embodiment depicted in FIGS. 5B to 5F, the Al composition ratio x of the location in which the etching rate is desired to be relatively high is set at 1. However, the Al composition ratio is not necessarily required to be 1. Regarding the thickness direction of the sacrificial layer 20, the Al composition ratio x may indicate a local maximum value at at least one inner location other than the interface with the substrate 10 and the interface with the semiconductor layer 30.

In the process of etching the sacrificial layer 20 depicted in FIGS. 2C to 3D, to reduce etching damages on the semiconductor layer 30, it is preferable to increase a ratio (etching selection ratio) of the etching rate of the sacrificial layer 20 with respect to the etching rate of the semiconductor layer 30 when an etchant for use in the process of etching the sacrificial layer 20 is used. For example, when the semiconductor layer 30 and the substrate 10 are formed of GaAs, the Al composition ratio x at a location where the Al composition ratio x inside the sacrificial layer 20 indicates a local maximum value is preferably larger than or equal to 0.5 and, more preferably, larger than or equal to 0.7. When the Al composition ratio x at the location where the Al composition ratio x inside the sacrificial layer 20 indicates a local maximum value is smaller than 0.5, a long time is required for etching for isolating the semiconductor layer 30 and the substrate 10 and, as a result, the semiconductor layer 30 and the substrate 10 are greatly damaged.

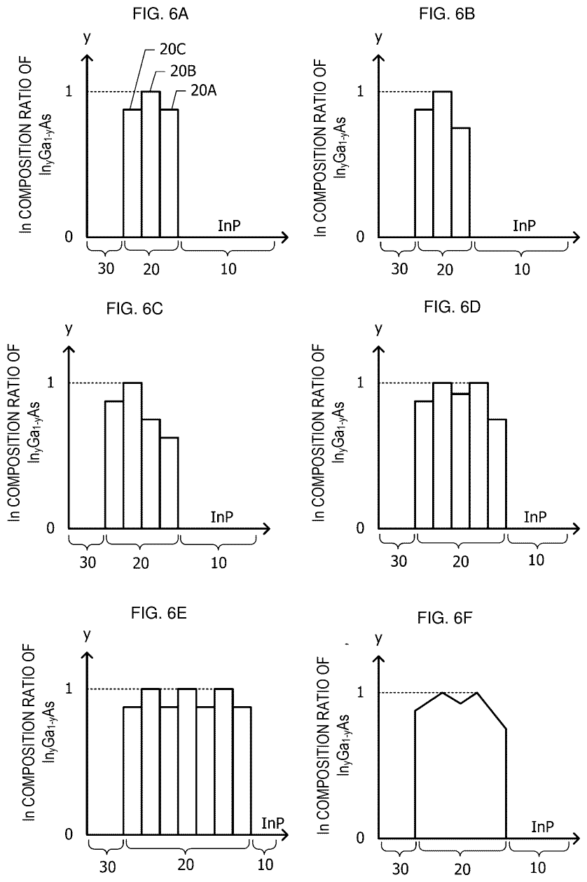

Next, with reference to FIGS. 6A to 6F, other modifications of the first embodiment are described.

While a GaAs substrate is used as the substrate 10 (FIG. 1A) in the first embodiment, a substrate made of another III-V-group compound semiconductor, for example, an InP substrate, may be used. When an InP substrate is used, In_{y}Ga_{1-y}As can be used as the sacrificial layer 20.

FIGS. 6A to 6F are graphs depicting distributions of In composition ratios y in a thickness direction in the sacrificial layers 20 of the epitaxially-grown substrates 40 according to other modifications of the first embodiment. In every case, an InP substrate is used as the substrate 10, and the sacrificial layer 20 is formed of In_{y}Ga_{1-y}As. The distributions of the In composition ratio y in the sacrificial layer 20 depicted in the graphs of FIGS. 6A to 6F are identical to the distributions of the Al composition ratio x in the sacrificial layer 20 depicted in the graphs of FIGS. 5A to 5F. The semiconductor layer 30 includes a layer made of a semiconductor material having lattice matching with the InP substrate, for example, InP.

The etching rate of InGaAs with respect to an acidic etchant or an alkaline etchant increases as the In composition ratio y increases. Thus, the distribution of the In composition ratio y in the sacrificial layer 20 is made into any of the distributions depicted in the graphs of FIGS. 6A to 6F, and an excellent effect similar to that of the first embodiment and its modifications depicted in the graphs of FIGS. 5A to 5F can be thereby obtained. For etching removal of the sacrificial layer 20 with priority with respect to the semiconductor layer 30 and the substrate 10, it is preferable to set the In composition ratio y larger than or equal to 0.5. For example, when the semiconductor layer 30 and the substrate 10 are formed of InP, the In composition ratio y at a location where the In composition ratio y inside the sacrificial layer 20 indicates a local maximum value is preferably larger than or equal to 0.5 and, more preferably, larger than or equal to 0.7.

As another modification, the sacrificial layer 20 may be formed of a four-element mixed-crystal semiconductor of AlₓIn_{y}Ga_{1-x-y}As. In this case, a GaAs substrate or an InP substrate may be used for the substrate 10. The distribution of a total composition ratio x+y of Al and In in the sacrificial layer 20 may be set to be a distribution similar to the distribution of the Al composition ratio x depicted in the graphs of FIGS. 5A to 5F. In addition, an InP substrate or a GaAs substrate may be used as the substrate 10 and InAIP may be used for the sacrificial layer 20.

### Second Embodiment

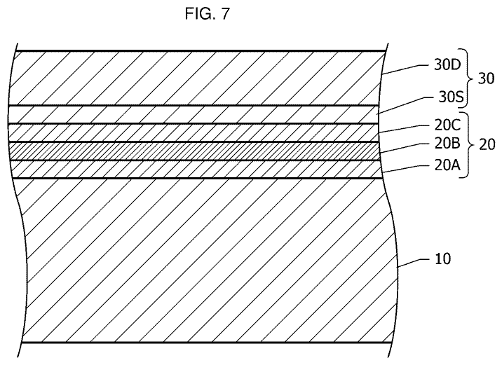

Next, with reference to FIG. 7, an epitaxially-grown substrate according to a second embodiment is described. In the following, description of structures common to those of the epitaxially-grown substrate 40 according to the first embodiment described with reference to FIGS. 1A to 3D is omitted.

FIG. 7 is a sectional view of the epitaxially-grown substrate 40 according to the second embodiment. Also in the second embodiment, as with the first embodiment, the epitaxially-grown substrate 40 includes the substrate 10, the sacrificial layer 20, and the semiconductor layer 30. In the second embodiment, the semiconductor layer 30 includes a stopper layer 30S epitaxially grown from the sacrificial layer 20 and a device layer 30D epitaxially grown from the stopper layer 30S.

The device layer 30D includes a layer made of a compound semiconductor having lattice matching with the substrate 10, for example, a layer made of a compound semiconductor identical to that of the substrate 10. The stopper layer 30S has a function of protecting the device layer 30D from the etchant in the process of etching the sacrificial layer 20 (FIGS. 2C, 3A, 3C, and 3D). Therefore, in wet etching using the etchant for etching the sacrificial layer 20, the etching rate of the stopper layer 30S is lower than the etching rate of a layer of the device layer 30D as an interface with the stopper layer 30S.

By way of example, when the sacrificial layer 20 is formed of AlGaAs or AlAs and the device layer 30D includes an AlGaAs layer, an AlGaInP layer, GalnP layer, AlInP layer, GaInAs layer, or the like can be used as the stopper layer 30S. By adjusting the composition ratio of the III-group element of the mixed-crystal semiconductor configuring the stopper layer 30S, it is possible to almost match the lattice constant of the stopper layer 30S with the lattice constant of the substrate 10 made of GaAs. Note that even if the lattice constants do not completely match, it is possible to suppress the occurrence of dislocation in the stopper layer 30S by making the thickness of the stopper layer 30S to the extent that distortion mitigation does not occur. Also, impurity concentrations may be varied between the stopper layer 30S and the device layer 30D and impurity concentration dependency of the etching rate may be used.

### Third Embodiment

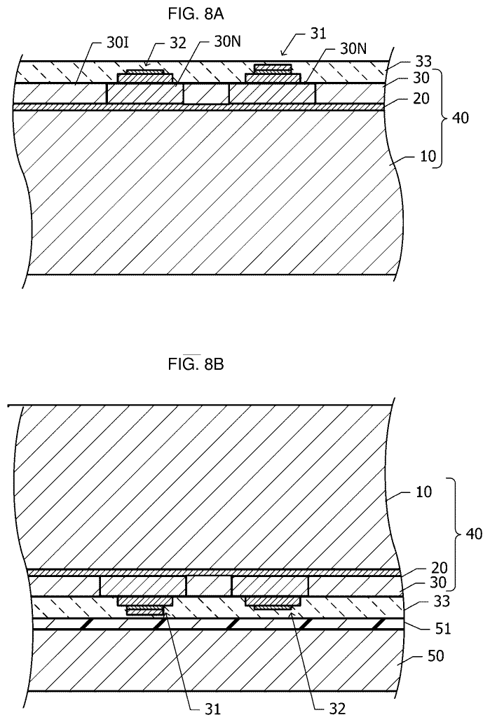

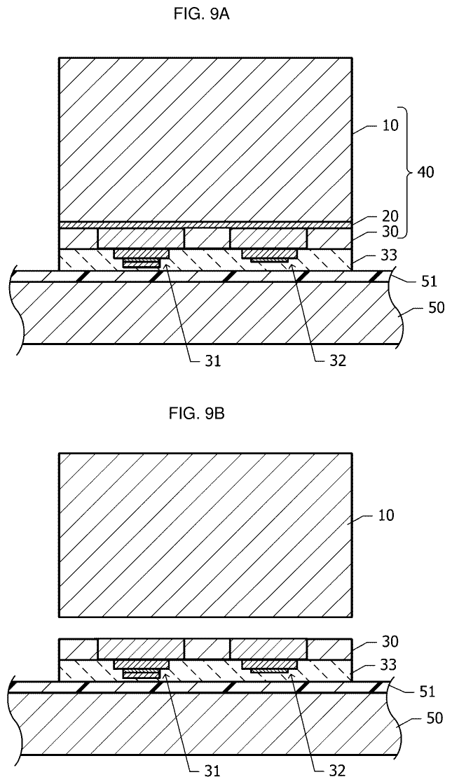

Next, with reference to FIGS. 8A to 9B, a semiconductor device manufacturing method using an epitaxially-grown substrate according to a third embodiment is described. FIGS. 8A to 9B are sectional views of a semiconductor device according to the third embodiment in the course of manufacture.

As depicted in FIG. 8A, the epitaxially-grown substrate 40 according to the first embodiment is prepared. The epitaxially-grown substrate 40 includes the substrate 10, the sacrificial layer 20, and the semiconductor layer 30 made of n-type GaAs. Part of the semiconductor layer 30 is made highly resistant to form an element isolation region 30I. A plurality of active regions 30N made of n-type GaAs electrically isolated from one another by the element isolation region 301 are delimited.

On each of the plurality of active regions 30N of the semiconductor layer 30, semiconductor elements such as a transistor 31 and a diode 32 are formed. The transistor 31 is a heterojunction bipolar transistor including, for example, a collector layer made of n-type GaAs, a base layer made of p-type GaAs, and an emitter layer made of n-type InGaP. The diode 32 includes, for example, a cathode layer made of n-type GaAs and an anode layer made of p-type GaAs formed in the same process as that for the collector layer and the base layer of the transistor 31. The active regions 30N are used as a current path for supplying carriers to the collector layer of the transistor 31 and the cathode layer of the diode 32.

On the semiconductor layer 30, an insulating film 33 for covering the transistor 31 and the diode 32 is formed. As the insulating film 33, an inorganic insulating material such as silicon nitride, an insulating resin, or the like is used.

As depicted in FIG. 8B, with a surface where the semiconductor layer 30 is formed being opposed to the preliminary substrate 50, the epitaxially-grown substrate 40 is laminated onto the preliminary substrate 50 via the adhesive layer 51. More specifically, the insulating film 33 is bonded to the preliminary substrate 50.

As depicted in FIG. 9A, the epitaxially-grown substrate 40 and the insulating film 33 are isolated into a plurality of small pieces by being cut with a dicing machine. In FIG. 9A, only one small piece is depicted. As depicted in FIG. 9B, the substrate 10 is isolated from the semiconductor layer 30 by etching removal of the sacrificial layer 20 of the epitaxially-grown substrate 40. With the process so far, a plurality of thin electronic circuit chips each including the transistor 31 and the diode 32 are obtained.

By way of example, by separating these electronic circuit chips from the preliminary substrate 50 and jointing the semiconductor layer 30 to another electronic circuit chip including a silicon substrate, it is possible to fabricate an electronic circuit component including a silicon-based electronic circuit element and a compound-semiconductor-group electronic circuit element.

Next, an excellent effect of the third embodiment is described.

Also in the third embodiment, as with the first embodiment, the occurrence of a crack in the semiconductor layer 30 can be suppressed in the process of isolating the substrate 10 from the semiconductor layer 30 depicted in FIG. 9B.

For the heterojunction transistor 31, an n-type compound semiconductor is used as a collector layer. For the purpose of forming a current path in the semiconductor layer 30 for supplying carries to the collector layer, the semiconductor layer 30 preferably includes an n-type compound semiconductor layer. In the process of etching the sacrificial layer 20 depicted in FIG. 9B, since the transistor 31 and the diode 32 are covered with the insulating film 33, they are not exposed to the etchant for etching the sacrificial layer 20. Thus, the transistor 31 and the diode 32 may include a compound semiconductor layer with an etching selection ratio with the sacrificial layer 20 being not sufficiently large.

Each of the above-described embodiments is merely an example, and it goes without saying that partial replacement or combination of the structures described in different embodiments is possible. Operations and effects similar to those by similar structures of the plurality of embodiments are not mentioned one by one for each embodiment. Furthermore, the present disclosure is not limited to the above-described embodiments. For example, it should be obvious for a person skilled in the art that various changes, improvements, combinations, and so forth are possible.

The following disclosure is disclosed based on the above-described embodiments in the specification.

<1> An epitaxially-grown substrate including a substrate made of a III-V-group compound semiconductor containing Ga or In as a III-group element; a sacrificial layer epitaxially grown on the substrate; and a semiconductor layer epitaxially grown on the sacrificial layer. The sacrificial layer includes a layer made of a mixed-crystal semiconductor containing Al or In as a III-group element, a composition ratio of Al or In varies in a thickness direction, and a location indicating a local maximum value of the composition ratio of Al or In is positioned inside other than a lower surface and an upper surface of the sacrificial layer.

<2> The epitaxially-grown substrate according to <1>, in which the layer made of the mixed-crystal semiconductor included in the sacrificial layer contains Ga as a III-group element in addition to Al or In, and contains at least one of As and P as a V-group element, and a maximum value of the composition ratio of Al or In is larger than or equal to 0.5.

<3> The epitaxially-grown substrate according to <1> or <2>, in which in the sacrificial layer, a composition ratio of Al or In of a portion in contact with the substrate is smaller than a composition ratio of Al or In of a portion in contact with the semiconductor layer.

<4> The epitaxially-grown substrate according to any one of <1> to <3>, in which the composition ratio of Al or In has the local maximum value at a plurality of locations of the sacrificial layer in the thickness direction.

<5> The epitaxially-grown substrate according to any one of <1> to <4>, in which the semiconductor layer has a thickness thinner than a thickness of the substrate and thicker than a thickness of the sacrificial layer.

<6> The epitaxially-grown substrate according to any one of <1> to <5>, in which the substrate is formed of GaAs or InP, and the semiconductor layer includes a layer made of a semiconductor having lattice matching with the substrate.

<7> The epitaxially-grown substrate according to any one of <1> to <6>, in which the semiconductor layer includes a stopper layer in contact with the sacrificial layer, and an etching rate of the stopper layer is lower than an etching rate of the sacrificial layer in wet etching using an acidic etchant or an alkaline etchant.

<8> The epitaxially-grown substrate according to any one of <1> to <7>, in which the semiconductor layer includes a layer made of an N-type semiconductor.

<9> The epitaxially-grown substrate according to any one of <1> to <8>, in which in wet etching using an acidic etchant or an alkaline etchant, a portion of the sacrificial layer in which an etching rate is maximum is positioned inside other than the lower surface and the upper surface of the sacrificial layer.

<10> A semiconductor device manufacturing method including forming at least one semiconductor element of a transistor and a diode on the semiconductor layer of the epitaxially-grown substrate according to any one of <1> to <9>; and performing etching removal of the sacrificial layer to separate the substrate from the semiconductor layer.

What is claimed is:

1. An epitaxially-grown substrate comprising:
a substrate including a III-V-group compound semiconductor including Ga or In as a III-group element;
a sacrificial layer epitaxially grown on the substrate; and
a semiconductor layer epitaxially grown on the sacrificial layer, wherein
the sacrificial layer includes a layer including a mixed-crystal semiconductor including Al or In as a III-group element, a composition ratio of Al or In varies in a thickness direction, and a location indicating a local maximum value of the composition ratio of Al or In is inside other than a lower surface and an upper surface of the sacrificial layer.

2. The epitaxially-grown substrate according to claim 1, wherein
the layer including the mixed-crystal semiconductor included in the sacrificial layer includes Ga as a III-group element in addition to Al or In, and includes at least one of As and P as a V-group element, and a maximum value of the composition ratio of Al or In is larger than or equal to 0.5.

3. The epitaxially-grown substrate according to claim 1, wherein
in the sacrificial layer, a composition ratio of Al or In of a portion in contact with the substrate is smaller than a composition ratio of Al or In of a portion in contact with the semiconductor layer.

4. The epitaxially-grown substrate according to claim 1, wherein
the composition ratio of Al or In has the local maximum value at a plurality of locations of the sacrificial layer in the thickness direction.

5. The epitaxially-grown substrate according to claim 1, wherein
the semiconductor layer has a thickness thinner than a thickness of the substrate and thicker than a thickness of the sacrificial layer.

6. The epitaxially-grown substrate according to claim 1, wherein
the substrate is formed of GaAs or InP, and the semiconductor layer includes a layer including a semiconductor having lattice matching with the substrate.

7. The epitaxially-grown substrate according to claim 1, wherein
the semiconductor layer includes a stopper layer in contact with the sacrificial layer, and an etching rate of the stopper layer is lower than an etching rate of the sacrificial layer in wet etching using an acidic etchant or an alkaline etchant.

8. The epitaxially-grown substrate according to claim 1, wherein
the semiconductor layer includes a layer including an N-type semiconductor.

9. The epitaxially-grown substrate according to claim 1, wherein
in wet etching using an acidic etchant or an alkaline etchant, a portion of the sacrificial layer in which an etching rate is maximum is inside other than the lower surface and the upper surface of the sacrificial layer.

10. A semiconductor device manufacturing method comprising:
forming at least one semiconductor element of a transistor and a diode on the semiconductor layer of the epitaxially-grown substrate according to claim 1; and
performing etching removal of the sacrificial layer to separate the substrate from the semiconductor layer.

11. The epitaxially-grown substrate according to claim 2, wherein
in the sacrificial layer, a composition ratio of Al or In of a portion in contact with the substrate is smaller than a composition ratio of Al or In of a portion in contact with the semiconductor layer.

12. The epitaxially-grown substrate according to claim 2, wherein
the composition ratio of Al or In has the local maximum value at a plurality of locations of the sacrificial layer in the thickness direction.

13. The epitaxially-grown substrate according to claim 2, wherein
the semiconductor layer has a thickness thinner than a thickness of the substrate and thicker than a thickness of the sacrificial layer.

14. The epitaxially-grown substrate according to claim 2, wherein
the substrate is formed of GaAs or InP, and the semiconductor layer includes a layer including a semiconductor having lattice matching with the substrate.

15. The epitaxially-grown substrate according to claim 2, wherein
the semiconductor layer includes a stopper layer in contact with the sacrificial layer, and an etching rate of the stopper layer is lower than an etching rate of the sacrificial layer in wet etching using an acidic etchant or an alkaline etchant.

16. The epitaxially-grown substrate according to claim 2, wherein
the semiconductor layer includes a layer including an N-type semiconductor.

17. The epitaxially-grown substrate according to claim 2, wherein
in wet etching using an acidic etchant or an alkaline etchant, a portion of the sacrificial layer in which an etching rate is maximum is inside other than the lower surface and the upper surface of the sacrificial layer.

18. A semiconductor device manufacturing method comprising:
forming at least one semiconductor element of a transistor and a diode on the semiconductor layer of the epitaxially-grown substrate according to claim 2; and
performing etching removal of the sacrificial layer to separate the substrate from the semiconductor layer.
